(19) United States
(12) Patent Application Publication
(10) Pub. No.: US 2019/0176046 A1
(43) Pub. Date: Jun. 13, 2019

(54) TOY WITH USER-OPERABLE LIGHT

(71) Applicant: Jay At Play International Hong Kong Limited d/b/a Jay At Play, Kowloon (HK)

(72) Inventor: Joseph A. Sutton, West New York, NJ (US)

(21) Appl. No.: 15/836,062

(22) Filed: Dec. 8, 2017

(51) Int. Cl. A63H 3/00; A63H 3/28; H03K 17/96

(52) U.S. Cl. CPC A63H 3/006; A63H 3/28; A63H 2200/00; H03K 17/9625; H03K 17/962

(57) ABSTRACT

A toy includes a body and a head coupled to the body. The head includes a face region. An appendage is coupled to at least one of the body or the head and is made at least partly from a material transmissive to light. A light emitting element communicates with the appendage. A first sensor is electrically coupled to the light emitting element and operable to activate the light emitting element upon detecting the touch of a user. A second sensor is electrically coupled to the light emitting element and operable to deactivate the light emitting element upon detecting air movement.

### BACKGROUND

The present invention relates to toys, and more particularly to toys having a light operable by a user.

### SUMMARY

In one embodiment, the invention provides a toy including a body and a head coupled to the body, the head including a face region. An appendage is coupled to at least one of the body or the head and is made at least partly from a material transmissive to light. A light emitting element communicates with the appendage. A first sensor is electrically coupled to the light emitting element and operable to activate the light emitting element upon detecting the touch of a user. A second sensor is electrically coupled to the light emitting element and operable to deactivate the light emitting element upon detecting air movement.

In another embodiment, the invention provides a toy including a body and a head coupled to the body. A light emitting element is positioned inside at least one of the body or the head and behind a material that is transmissive to light emitted from the light emitting element so that the light emitting element is not exposed outside the toy but the light emitted from the light emitting element is viewable from outside the toy. A first sensor is electrically coupled to the light emitting element and operable to activate the light emitting element upon detecting the touch of a user. A second sensor is electrically coupled to the light emitting element and operable to deactivate the light emitting element upon detecting air movement. A sound emitting element is positioned within at least one of the body or the head and the first sensor or the second sensor is further operable to activate the sound emitting element.

In yet another embodiment, the invention provides a toy including a body and a head coupled to the body, the head including a face region. An appendage is coupled to at least one of the body or the head and is made at least partly from a material transmissive to light. A light emitting element communicates with the appendage. A blow sensor is electrically coupled to the light emitting element and is operable to (a) activate the light emitting element upon detecting air movement, and (b) subsequent to the activation in step (a), deactivate the light emitting element upon detecting subsequent air movement.

The invention further provides a method of playing with a toy having a body and a head coupled to the body. The head includes a face region. The method includes touching the face region to trigger a touch sensor, the touch sensor activating a light emitting element within the toy such that a portion of the toy illuminates, and blowing on the toy in a region adjacent to the illuminated portion of the toy to trigger a blow sensor, the blow sensor deactivating the light emitting element upon detecting air movement. In one aspect, the method further includes the blow sensor activating a sound emitting element within the toy

Other aspects of the invention will become apparent by consideration of the detailed description and accompanying drawings.

### BRIEF DESCRIPTION OF THE DRAWINGS

FIG. 1 is a perspective view of a toy embodying the present invention.

FIG. 2 is a front view of the toy of FIG. 1.

FIG. 3 is a view of the internal hardware removed from the toy of FIG. 1.

FIG. 4 is bottom view of the toy of FIG. 1, showing the control unit removed from a cavity in the toy.

FIG. 5 is a bottom view of the toy like FIG. 4, showing an opposite side of the control unit.

FIG. 6 is a front view of the toy, schematically illustrating the location of the hardware in the head.

FIG. 7 is a front view of the toy, showing the appendage illuminated by a light emitting device.

FIG. 8 is a perspective view of another toy embodying the invention.

FIG. 9 is a partial view of the toy of FIG. 8 with the bow illuminated.

FIG. 10 is a front view of another toy embodying the invention.

FIG. 11 is a partial view of the toy of FIG. 10 with the bow illuminated.

FIG. 12 is a front view of yet another toy embodying the invention.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

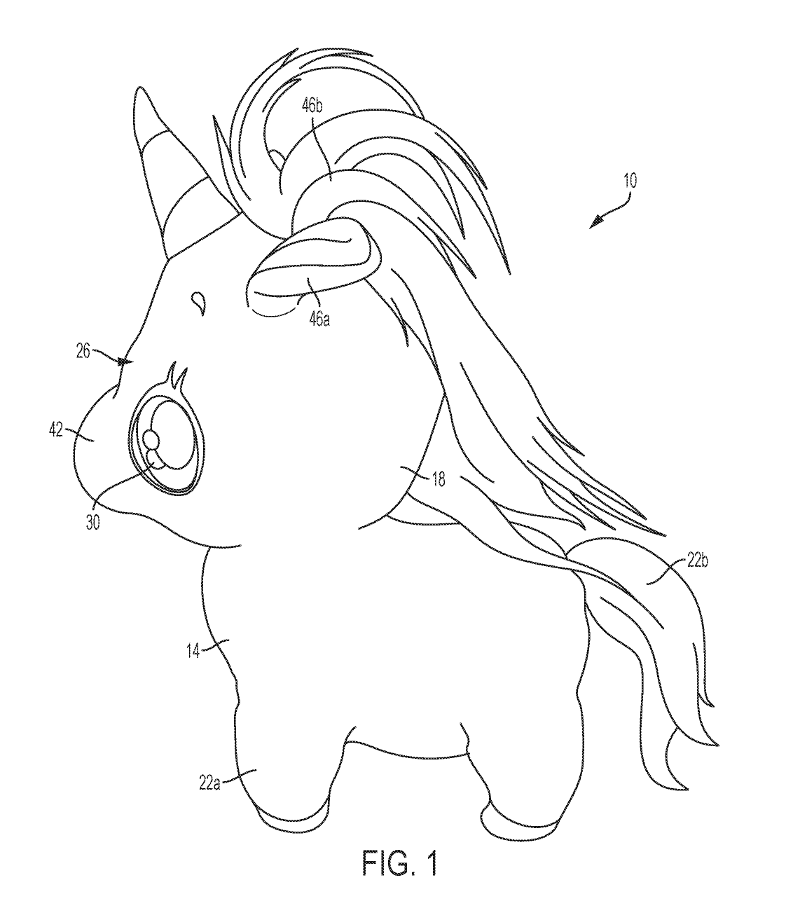

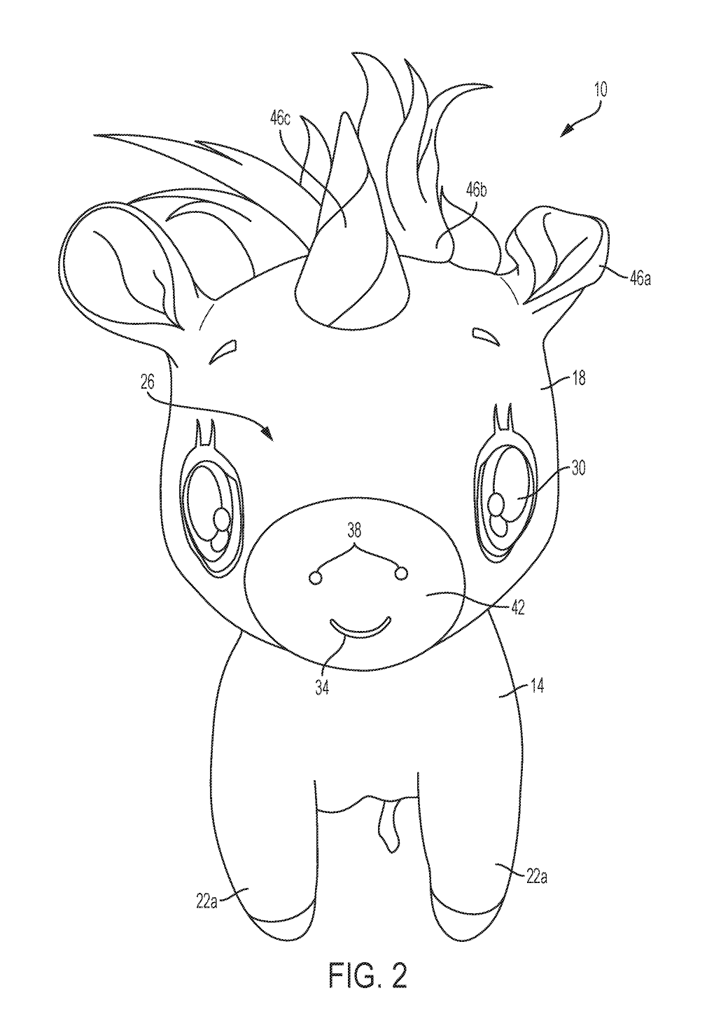

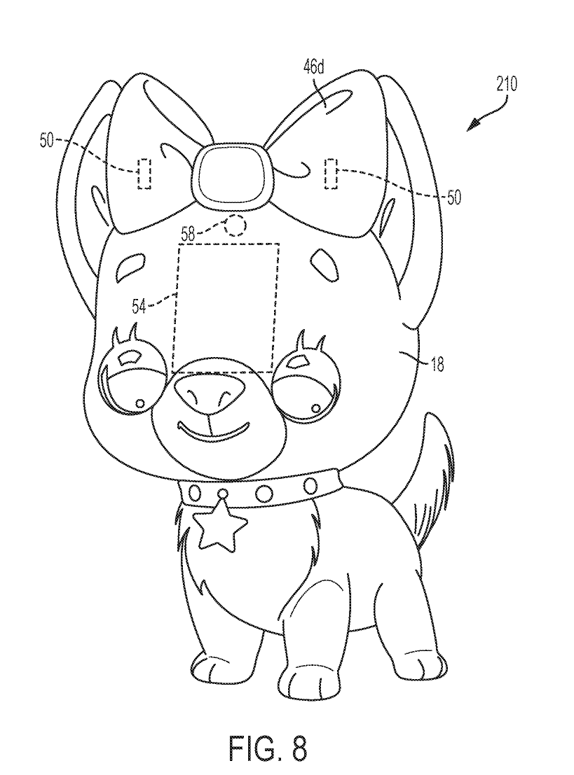

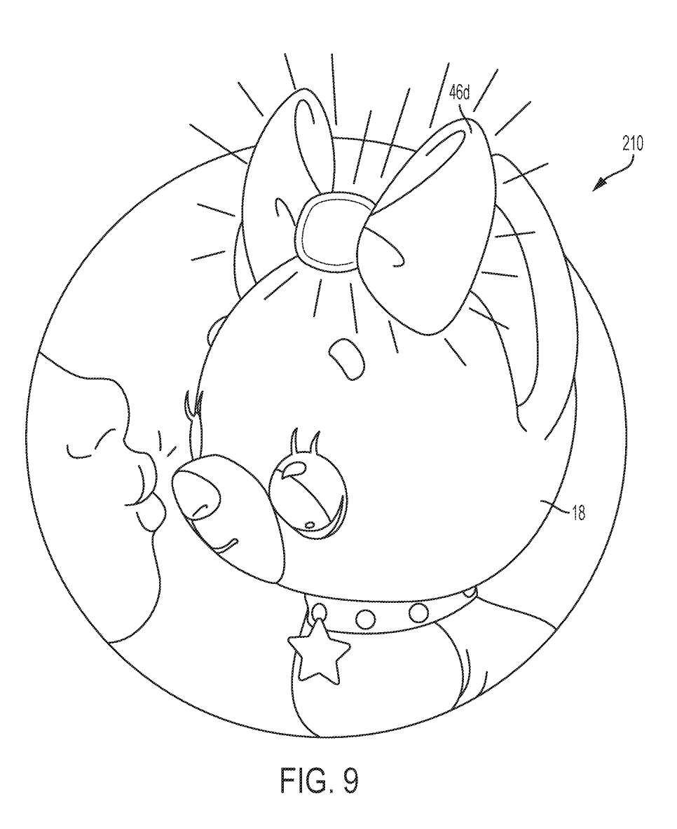

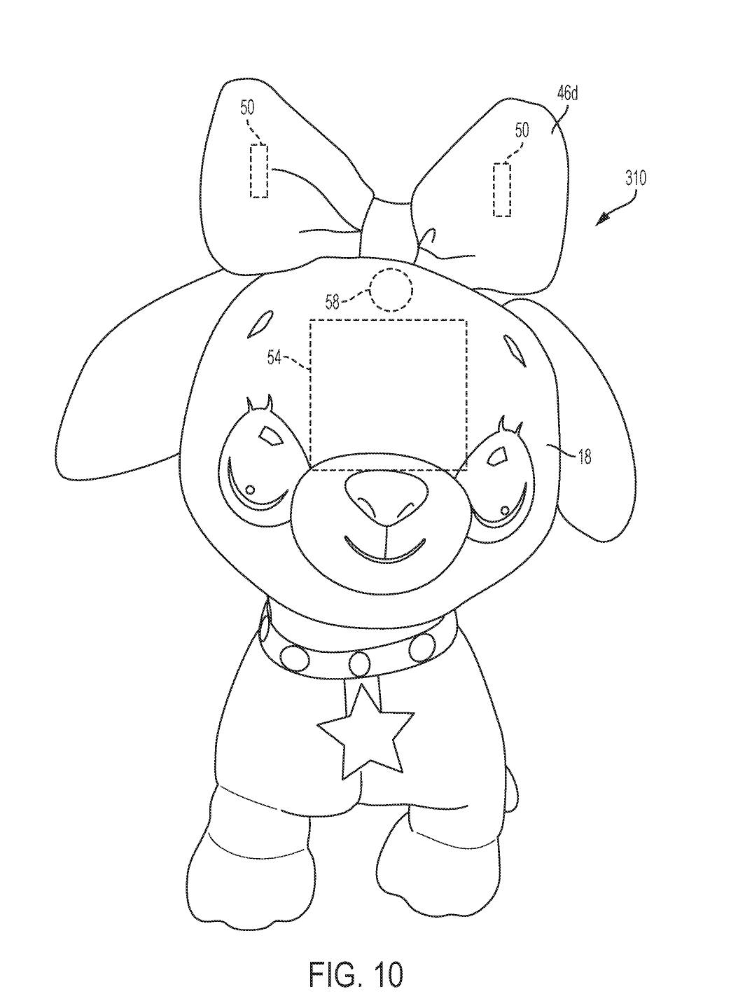

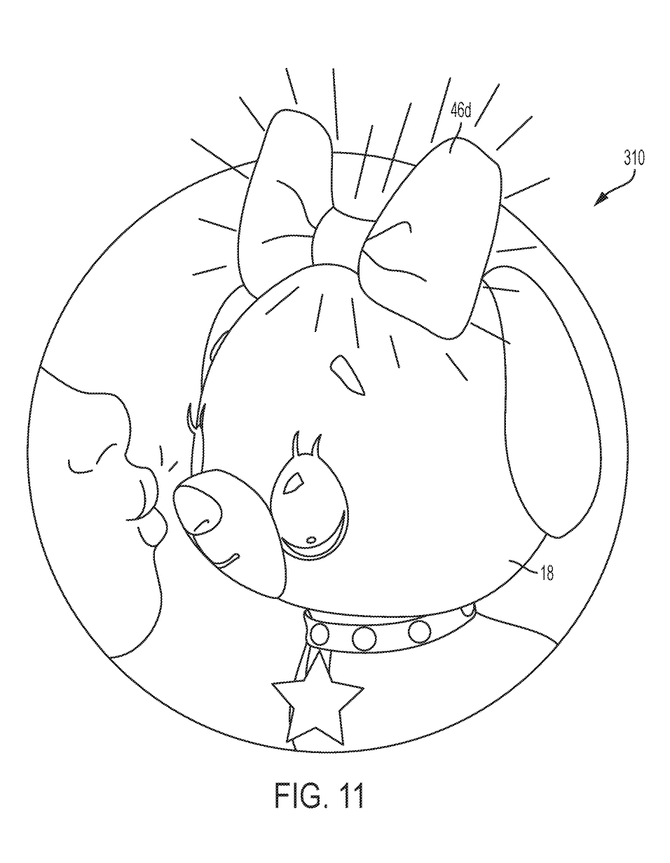

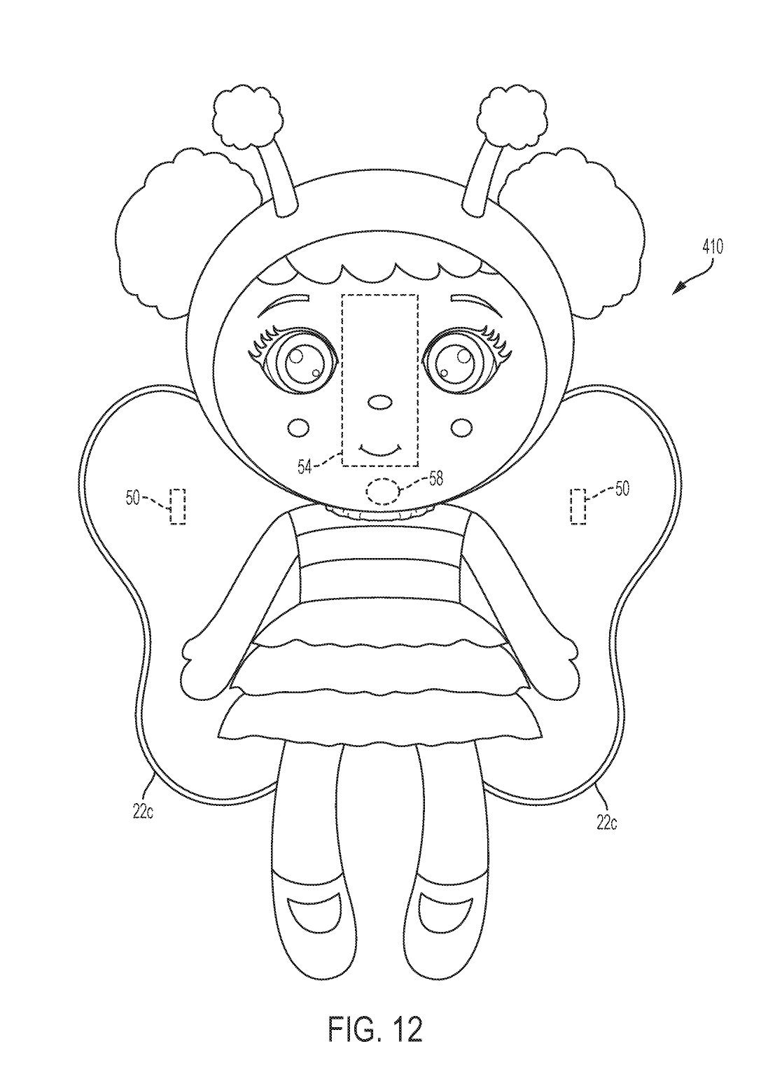

FIGS. 1-7 illustrate a first embodiment of a toy 10 according to the present invention. The illustrated toy 10 is a plush toy taking the form of a unicorn. However, in other embodiments, the toy 10 can be a toy taking other forms, such as the cat illustrated in FIGS. 8 and 9, the dog illustrated in FIGS. 10 and 11, the butterfly doll illustrated in FIG. 12, or any other characters. The characters that may be displayed include, for example, commonly known movie or television characters, animated characters, animals, humans, inanimate objects, fantasy creatures or characters, historical characters, characters from books or other sources, or other articles, whether real or imagined. The materials used to form the characters may be any suitable materials, including plush fabric, knit fabric, woven fabric, stuffing materials, textiles, plastic, rubber, or any other suitable material for use as a toy.

As shown in FIGS. 1-7, the unicorn toy 10 includes a body 14 and a head 18 coupled to the body 14. The body 14 can include appendages 22 representing features of the creature or character, such as legs 22a and a tail 22b, as well as other accessories associated with the toy 10. For example, the unicorn toy 10 could include a saddle, wings, or other body appendages 22. One of ordinary skill in the art will understand that different creatures or characters will include different body appendages 22 depending on the type of creature or character depicted.

The head 18 includes a face region 26 having features typical of a face of a creature or character. The illustrated face region 26 includes indicia representing eyes 30, indicia representing a mouth 34, and indicia representing nostrils of a nose 38. The face region 26 further includes a protrusion representing a snout 42. As used herein and in the appended claims, the face region 26 includes at least the area containing and generally surrounding the facial indicia 30, 34, and 38, as well as the area containing and generally surrounding the snout protrusion 42. One of ordinary skill in the art will understand that different creatures or characters will include different facial indicia depending on the type of creature or character depicted.

The head 18 can further include appendages 46 representing features of the creature or character as well as other accessories associated with the toy 10. The illustrated head includes appendages representing ears 46a, an appendage representing a mane 46b, and an appendage representing a horn 46c. Each of the body appendages 22 and the head appendages 46 can be coupled to the respective body 14 or head 18 in any suitable manner, such as stitching, gluing, integrally forming, or otherwise securing.

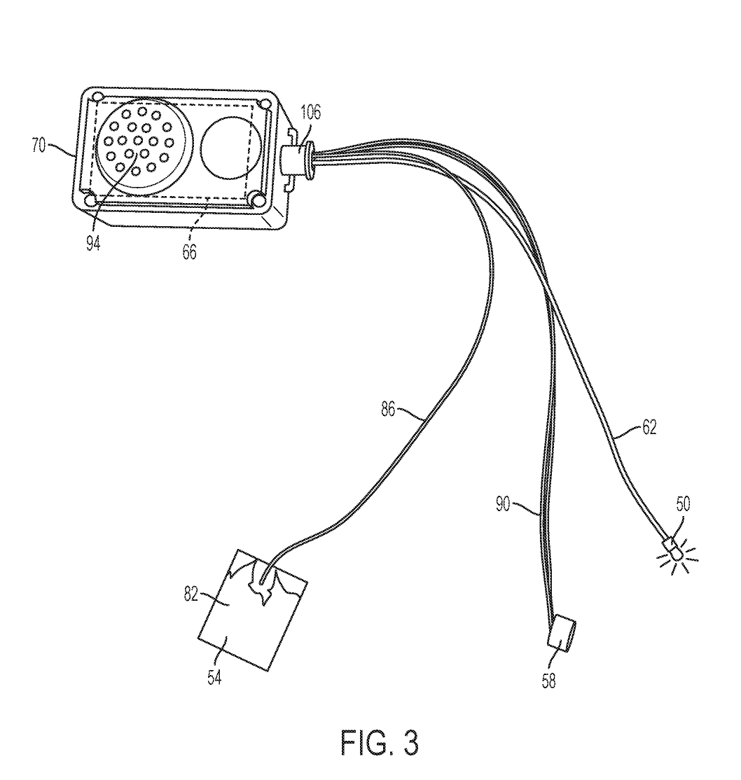

The toy 10 further includes a light-up/blow-out feature that enhances the play value and enjoyability of the toy 10. With reference to FIGS. 3-6, the light-up/blow-out feature includes a light emitting element 50, a first sensor 54 electrically coupled to the light emitting element 50 and operable to activate the light emitting element 50 upon detecting the touch of a user, and a second sensor 58 electrically coupled to the light emitting element 50 and operable to deactivate the light emitting element 50 upon detecting air movement. FIG. 3 illustrates one example of the hardware components of the light-up/blow-out feature removed from the toy 10.

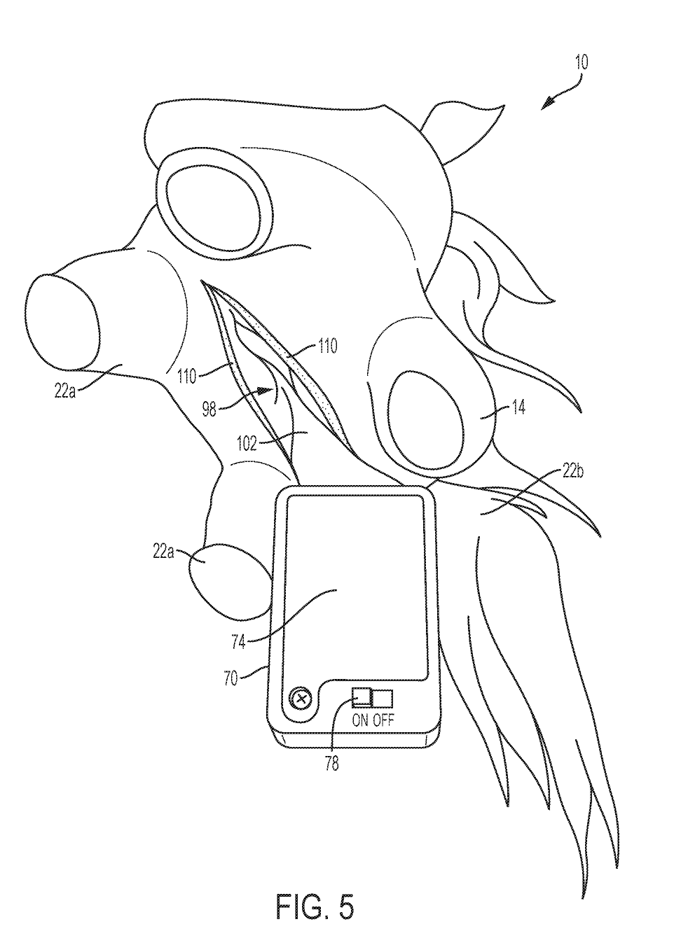

The light emitting element 50 can be any suitable device that generates light. Examples include LED's, incandescent or fluorescent bulbs, and the like. Fiber optic cables or light pipes can also be used if desired to transmit the light within the toy 10. The light emitting element 50 is electrically coupled via wires 62 to a circuit board, processor, or controller 66 (shown schematically in FIG. 3) that is retained within a housing 70. The housing 70 can also contain one or more batteries (not shown) for providing power to the light emitting element 50. The batteries can be accessed by a removable panel 74 (see FIG. 5) of the housing. The housing 70 can also include and/or support a switch 78 (see FIG. 5) operable to turn the light-up/blow-out feature on and off.

The first sensor 54 is a touch sensor and can include a capacitive sensor, a pressure sensor, or any other suitable type of sensor capable of detecting the touch or presence of a user. The sensor 54 illustrated in FIG. 3 is a capacitive sensor with a conductive sheet 82 that can be sized and configured for the desired placement within the toy 10. The first sensor 54 is also electrically coupled via wires 86 to the circuit board 66 within the housing 70, and is therefore electrically coupled to the light emitting element 50. The second sensor 58 detects air movement, air flow, or air pressure and is sometimes referred to as a blow sensor or airflow sensor. The second sensor 58 is also electrically coupled via wires 90 to the circuit board 66 within the housing 70, and is therefore electrically coupled to the light emitting element 50.

The light-up/blow-out feature can also include an optional sound feature, which in the illustrated embodiment, is a sound emitting element in the form of a speaker 94 supported within the housing 70. The circuit board 66 includes a sound storage device that can store one or more pre-recorded sounds. For example, in the illustrated unicorn toy 10, a pre-recorded bell or chime sound is stored in the sound storage device of the circuit board 66. In other toy embodiments, such as the cat of FIGS. 8 and 9, or the dog of FIGS. 10 and 11, the pre-recorded sound can be a meowing sound, a barking sound, or any other sound appropriately selected for the desired character represented by the toy. Other embodiments may include sounds such a spoken words, music, crying, bodily noises such as flatulence, and other sounds and combinations of sounds.

The circuit board 66 electrically couples each of the light emitting element 50, the first sensor 54, the second sensor 58, and the sound emitting element 94 together, and in the illustrated embodiment is configured such that detection of a user's touch by the first sensor 54 will activate the light emitting element 50 (i.e., turn the light on). To deactivate the light emitting element 50 (i.e., turn the light off), the user can blow toward and in the vicinity of the second sensor 58 to generate air movement/flow/pressure that will be detected by the second sensor 58. When the second sensor 58 is triggered by the air flow, the circuit board 66 turns off the light emitting element 50. In the illustrated embodiment that further includes the optional sound feature, triggering of the second sensor 58 further activates the sound emitting element 94 to play the pre-recorded sound. In this case, the bells or chimes play a magical-sounding tune once the light turns off. The circuit board 66 also includes a timer circuit that will turn off the light emitting element 50 (and also optionally trigger the sound emitting element 94) if a predetermined period of time passes before the second sensor 58 is triggered. This will help to preserve the battery life of the toy in the event a child fails to trigger the second sensor 58 to deactivate the light emitting element 50.

In other embodiments various circuit boards, controllers, or processors can be used, programmed, or configured to carry out these and other operations. For example, in some embodiments, the sound emitting device 94 might be triggered by the first sensor 54 instead of by the second sensor 58. In such an embodiment, a touch may first trigger the sound emitting device 94 to play the pre-recorded sound. The touch may also trigger the simultaneous or delayed activation of the light emitting element 50. The triggering of the second sensor 58 by a user may then deactivate the light. In yet another embodiment, the second sensor 58 may be operable to both activate and deactivate the light emitting element 50, such that a user blows on the blow sensor 58 once to first turn on the light, and then again to turn off the light. The optional sound feature may be incorporated such that the first and/or second blow by the user triggers the sound emitting element 94. In some embodiments, there may be two or more different pre-recorded sounds such that a first sound plays upon a sensor being triggered, and later, a second sound plays upon a sensor being triggered. One of ordinary skill in the art will understand how many different operational sequences can be achieved using the combination of some or all of the light emitting element 50, the first sensor 54, the second sensor 58, the circuit board 66, and the sound emitting element 94. In further embodiments the toy can have multiple first and/or second sensors at different locations about the toy to achieve various desired effects.

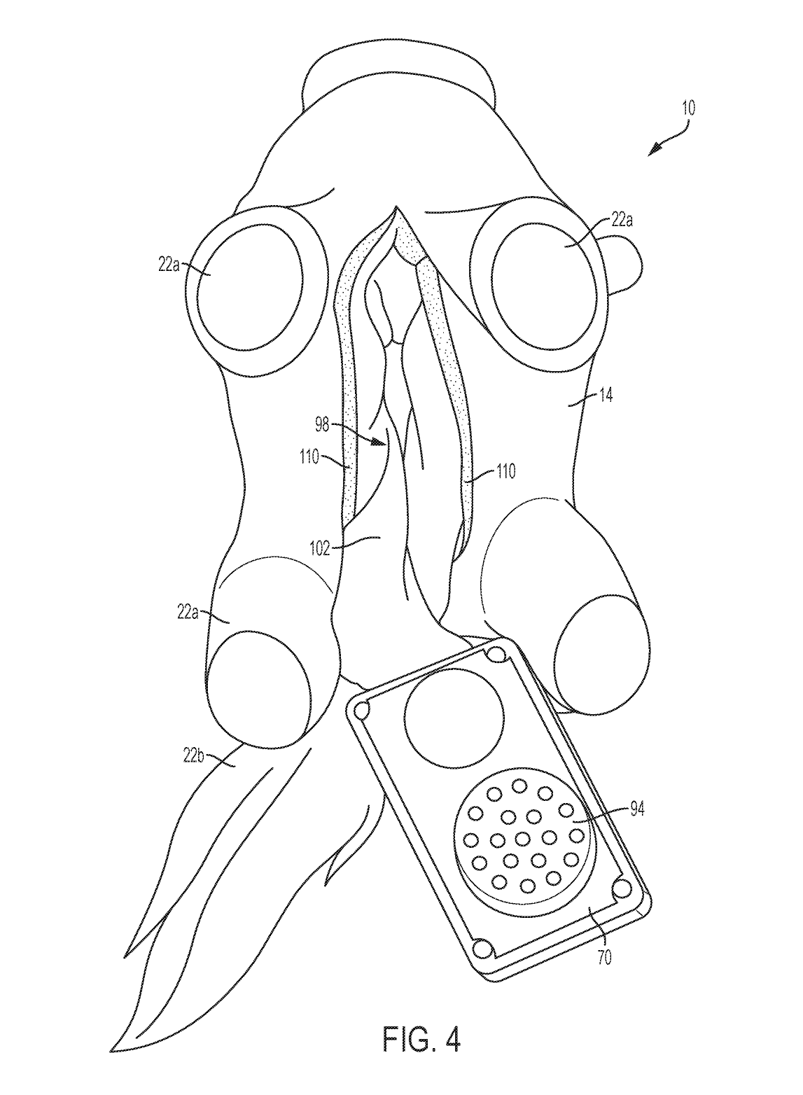

FIGS. 4-6 illustrate the light-up/blow-out feature provided in the toy 10. FIGS. 4 and 5 illustrate a cavity 98 formed in the bottom of the toy 10, and more specifically in the body 14 between the legs 22a. The cavity 98 is lined with a lining material 102 that prevents the filling material and any other internal features of the toy 10 from being accessible from the cavity 98. The housing 70 is removably stored within the cavity 98. The lining material 102 is secured to a boss 106 of the housing 70 (see FIG. 3) that defines the pass-through location for the wires 62, 86, 90. In the illustrated embodiment, the lining material is wrapped around and stitched about the boss 106 so that the wires 62, 86, and 90 are not accessible to a user. Only the removable battery panel 74 and the on/off switch 78 of the housing 70 are accessible, as shown in FIG. 5. To turn the device on, a user moves the on/off switch 78 to the on position. The user can then place the housing 70 within the cavity 98 and close the cavity 98 using the closure, which in the illustrated embodiment, takes the form of mating hook and loop fasteners 110 positioned on opposite sides of the cavity 98. In other embodiments, zippers, buttons, snaps, or other closure devices can alternatively be used.

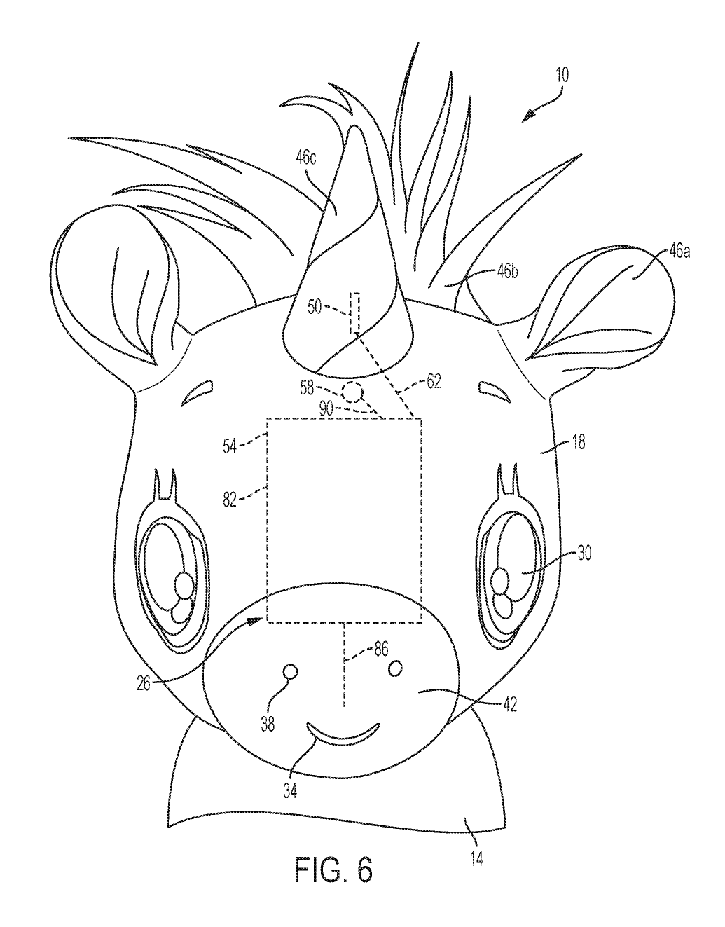

FIG. 6 schematically illustrates the routing of the wires 62, 86, and 90 and the locations within the head 18 where the light emitting element 50, the first sensor 54, and the second sensor 58 are positioned. The conductive sheet 82 of the first sensor 54 is located in the face region 26 underneath the material that defines the outer covering of the head 18. The conductive sheet 82 can extend from the snout protrusion 42 to just below the horn appendage 46c, and substantially between the two eyes 30. This provides a large area of the face region 26 where the touch of a user can activate the first sensor 58. For example a user who kisses the snout protrusion 42 will likely contact the conductive sheet 82 (e.g., with his or her lips and/or nose) to trigger the first sensor 54. Alternatively, a user can simply touch the face region 26 with his or her fingers to trigger the first sensor 54. The light emitting element 50 and the sensors 54, 58 can be held in place within the toy 10 by the filling material of the toy 10, by stitching, by adhesive and/or by other securing mechanisms. In other embodiments, the first sensor 54 could be in other locations (e.g., the side, the hind end, the legs, etc.), or there could be two or more touch sensors positioned in various regions of the toy 10.

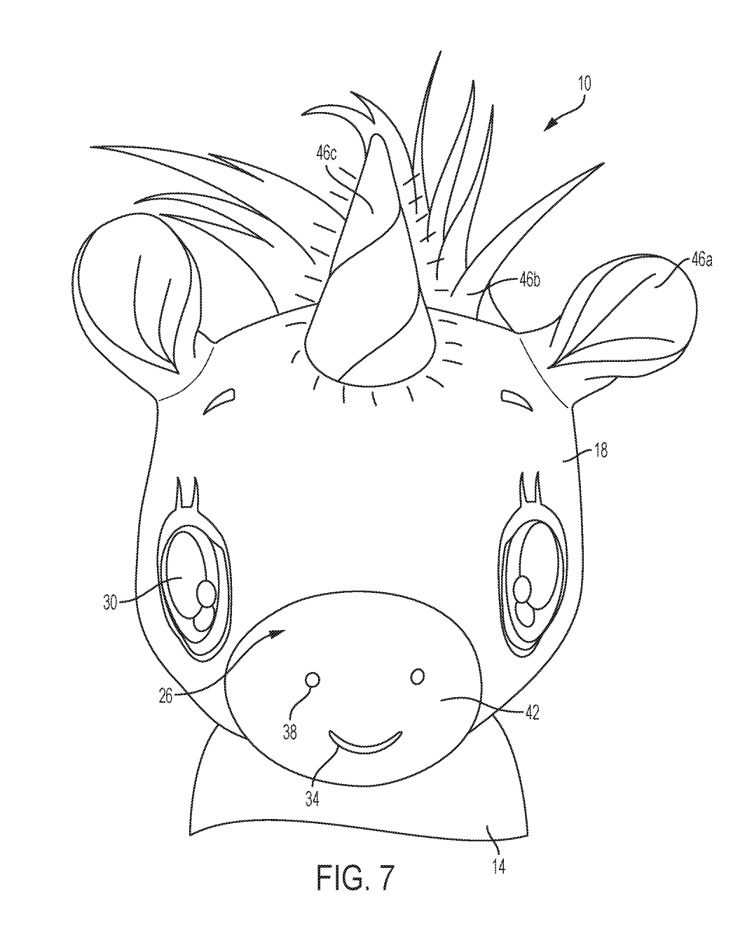

The light emitting element 50 communicates with the horn appendage 46c, and in the illustrated embodiment, is located at least partially or completely within the horn appendage 46c. In other embodiments the light emitting element 50 might be adjacent to the appendage, or could even be remote from the appendage but could use one or more light pipes to transmit the light to the appendage. The horn appendage 46c is made from a light-transmissive material so that when the first sensor 54 is triggered, the light emitting element 50 illuminates, causing the horn appendage 46c to light up, as shown in FIG. 7. The light emanates from the horn appendage 46c. In other embodiments, the light emitting element 50 need not be in an appendage, but could instead be in or behind a light-transmissive icon (e.g., a heart, flowers, etc.), emblem, or other feature formed on or in the body 14 and/or head 18.

The second, blow sensor 58 is positioned underneath the material that defines the outer covering of the head 18 and just below the horn appendage 46c. In other embodiments, it can be positioned in the appendage 46c. A user can therefore blow generally in the vicinity of the face region 26 and the horn appendage 46c to trigger the second sensor 58. Because the material that defines the outer covering of the head 18 is fabric, the airflow can pass through the material to trigger the second sensor 58. When the user blows in the general area of the second sensor 58, the light emitting element 50 is deactivated and the sound emitting element 94 is triggered to play the pre-recorded sound. Should the user fail to trigger the second sensor 58 within the predetermined time, the timer circuit will deactivate the light emitting element 50, and can also trigger the sound emitting element 94.

The unicorn toy 10 is fun and interactive for a child to play with. The child can give the unicorn toy 10 a kiss in the face region 26 or pet the snout protrusion 42, thereby triggering the first sensor 54 to activate the light emitting element 50 in the horn appendage 46c. This may be even more fun and exciting at night or when the child is in a darkened room. The child can then make a wish and blow out the light by blowing on the second sensor 58. The child will perceive that his or her blowing is actually blowing out the light. The optional, magical-sounding chime noise emitted from the sound emitting element 94 will provide a magical feeling to the child, who might now believe that their wish has been granted. As discussed above, modifications to the operational sequence, and the number and location of sensors, are contemplated and possible using the hardware and circuitry provided.

FIGS. 8 and 9 illustrate another embodiment of a cat toy 210 that operates in generally the same manner described above for the unicorn toy 10, except that it is a cat character instead of a unicorn. Like parts have been given like reference numerals. The light-up/blow-out feature operates in nearly the identical manner, except that the pre-recorded sound emitted by the sound emitting element 94 is a meowing sound. Specifically, a child may kiss or pet the cat toy 210 in the face region 26 to trigger the first sensor 54, thereby activating the light emitting element 50. In the cat toy 210, the light-transmissive head appendage 46d takes the form of a bow on top of the cat's head 18 that illuminates (see FIG. 9). In the illustrated embodiment, there are two light emitting elements 50, one in each side of the bow 46d. The second sensor 58 is just below the bow 46d so that when the child blows in that general area, the light in the bow 46d turns off. In another embodiment, the second sensor 58 could be in the bow 46d. The sound emitting element 94 is triggered to play the meowing sound. Therefore, the child will perceive that his or her blowing blows out the light in the bow 46d and makes the cat meow. As discussed above, modifications to the operational sequence, and the number and location of sensors, are contemplated and possible using the hardware and circuitry provided. For example, it is possible to have the cat toy 210 operate such that a user blowing on the blow sensor 58 triggers the sound emitting element 94 to emit the meowing sound, before or without the light illuminating and/or without any triggering of the first sensor 54.

FIGS. 10 and 11 illustrate yet another embodiment of a dog toy 310 that operates in generally the same manner described above for the cat toy 210, except that it is a dog character instead of a cat. Like parts have been given like reference numerals. The light-up/blow-out feature operates in nearly the identical manner, except that the pre-recorded sound emitted by the sound emitting element 94 is a barking sound.

FIG. 12 illustrates yet another embodiment of a butterfly toy 410 that operates in the same manner described above for the unicorn toy 10, except that it is a butterfly character instead of a unicorn. Like parts have been given like reference numerals. The light-up/blow-out feature operates in nearly the identical manner, except that the light emitting elements 50 communicate with, or is at least partially or completely within body appendages in the form of wings 22c.

Those skilled in the art will understand how the inventive light-up/blow-out feature can be applied to virtually any other character to provide a fun and interactive toy that children will enjoy. The placement and number of the light emitting element(s) 50, light-up appendages, and the sensors 54, 58 can be varied, depending upon the character, to other locations within heads, bodies, or other features of different toys. As discussed above, modifications to the operational sequence are contemplated and possible using the hardware and circuitry provided.

Various features and advantages of the invention are set forth in the following claims.

1. A toy comprising:
a body;
a head coupled to the body, the head including a face region;
an appendage coupled to at least one of the body or the head and being made at least partly from a material transmissive to light, wherein the appendage has a first end directly connected to at least one of the body or the head, and a second end spaced apart from the at least one of the body or the head;
a light emitting element communicating with the appendage;
a first sensor electrically coupled to the light emitting element and operable to activate the light emitting element upon detecting the touch of a user, the first sensor being a capacitive sensor having a conductive sheet positioned in the face region of the head beneath a material defining the face region; and
a second sensor electrically coupled to the light emitting element and operable to deactivate the light emitting element upon detecting air movement, the second sensor being a blow sensor positioned in the appendage or in the head and at least partly covered with a material that permits air from outside the toy to communicate with the blow sensor.

2. (canceled)

3. (canceled)

4. (canceled)

5. The toy of claim 1, wherein the toy takes the form of a unicorn, and wherein the appendage is a horn on the head.

6. The toy of claim 1, wherein the toy takes the form of a cat or dog, and wherein the appendage is a bow on the head.

7. The toy of claim 1, wherein the toy takes the form of a butterfly, and wherein the appendage is a wing coupled to the body.

8. The toy of claim 1, wherein the light emitting element, the first sensor, and the second sensor are electrically coupled via a circuit board, the circuit board being positioned in a housing.

9. The toy of claim 1, wherein at least one of the head and the body includes plush material.

10. (canceled)

11. The toy of claim 1, wherein the face region includes a protrusion representative of a snout of a creature.

12. (canceled)

13. The toy of claim 1, further comprising a sound emitting element positioned within at least one of the body or the head, the first sensor or the second sensor further operable to activate the sound emitting element.

14-18. (canceled)

19. A method of playing with a toy having a body and a head coupled to the body, the head including a face region, the method comprising:
touching the face region to trigger a capacitive touch sensor having a conductive sheet positioned in the face region beneath a material defining the face region, the touch sensor activating a light emitting element communicating with an appendage of the toy such that the appendage of the toy illuminates; and
blowing on the toy in a region adjacent to the illuminated appendage of the toy to trigger a blow sensor, the blow sensor deactivating the light emitting element upon detecting air movement.

20. The method of claim 19, wherein blowing on the toy to trigger the blow sensor further includes the blow sensor activating a sound emitting element within the toy.

21. (canceled)

22. The toy of claim 1, wherein the blow sensor is adjacent the face region.

23. The toy of claim 8, wherein the housing is removably positioned within a cavity in the body such that the housing can be removed from the cavity to operate an on/off switch on the housing.

24. The toy of claim 23, wherein the cavity is lined with a lining material that is secured to a portion of the housing.

25. The toy of claim 24, wherein the lining material is wrapped around and stitched to a boss on the housing.

26. The toy of claim 24, wherein wires electrically connecting the light emitting element, the first sensor, and the second sensor to the circuit board pass through the portion of the housing to which the lining material is secured such that the wires are not accessible within the cavity.

27. A plush toy comprising:
a plush body;
a plush head coupled to the body, the head including a face region;
an appendage coupled to at least one of the body or the head and being made at least partly from a material transmissive to light, wherein the appendage has a first end directly connected to at least one of the body or the head, and a second end spaced apart from the at least one of the body or the head;
a light emitting element communicating with the appendage;
a first sensor electrically coupled to the light emitting element and operable to activate the light emitting element upon detecting the touch of a user, the first sensor being a capacitive sensor having a conductive sheet positioned in the face region of the head beneath a material defining the face region; and
a second sensor electrically coupled to the light emitting element and operable to deactivate the light emitting element upon detecting air movement, the second sensor being a blow sensor positioned in the appendage or in the head and at least partly covered with a material that permits air from outside the toy to communicate with the blow sensor;
wherein the light emitting element, the first sensor, and the second sensor are electrically coupled via a circuit board, the circuit board being positioned in a housing;
wherein the housing is removably positioned within a lined cavity in the body such that the housing can be removed from the cavity; and
wherein wires electrically connecting the light emitting element, the first sensor, and the second sensor to the circuit board pass through the portion of the housing to which lining material is secured such that the wires are not accessible within the cavity.

28. The toy of claim 27, further comprising a sound emitting element positioned within the housing, the first sensor or the second sensor further operable to activate the sound emitting element.

29. The toy of claim 28, wherein the second sensor activates the sound emitting element simultaneously with deactivating the light emitting element.

30. The toy of claim 27, wherein the lining material in the lined cavity is wrapped around and stitched to a boss on the housing.
